(19) United States
(12) Patent Application Publication
(10) Pub. No.: US 2020/0303532 A1
(43) Pub. Date: Sep. 24, 2020

(54) GaN-BASED FIELD EFFECT TRANSISTOR

(71) Applicant: WIN Semiconductors Corp., Tao Yuan City (TW)

(72) Inventors: Che-Kai LIN, Tao Yuan City (TW); Chieh-Chih HUANG, Tao Yuan City (TW); Wei-Chou WANG, Tao Yuan City (TW); Walter Tony WOHLMUTH, Tao Yuan City (TW)

(21) Appl. No.: 16/359,104

(22) Filed: Mar. 20, 2019

(51) Int. Cl. H01L 29/778; H01L 23/31

(52) U.S. Cl. CPC H01L 29/7783; H01L 23/3171

(57) ABSTRACT

A GaN-based field effect transistor comprises a semiconductor substrate, an epitaxial structure formed on the semiconductor substrate, a source electrode, a drain electrode, and a gate electrode. The epitaxial structure comprises a buffer layer, a channel layer, a spacer layer, an n-type doped barrier layer, a barrier layer, and a capping layer, sequentially. The epitaxial structure has a source recess and a drain recess. A bottom of the source recess is defined by the n-type doped barrier layer or the spacer layer. A bottom of the drain recess is defined by the n-type doped barrier layer or the spacer layer. The source electrode is formed in the source recess. The drain electrode is formed in the drain recess. The gate electrode is formed on the capping layer between the source electrode and the drain electrode.

### FIELD OF THE INVENTION

The present invention is related to a GaN-based field effect transistor, especially a GaN-based field effect transistor having an n-type doped barrier layer.

### BACKGROUND OF THE INVENTION

Please refer to FIG. 3A, which shows a cross-sectional schematic view of an embodiment of a GaN-based field effect transistor of conventional technology. A GaN-based field effect transistor 9 of the conventional technology comprises: a semiconductor substrate 90, a buffer layer 91, a channel layer 92, a spacer layer 93, a barrier layer 94, a capping layer 95, a protection layer 96, a source electrode 97, a drain electrode 99, and a gate electrode 98. The buffer layer 91 is formed on the semiconductor substrate 90. The channel layer 92 is formed on the buffer layer 91. The spacer layer 93 is formed on the channel layer 92. The barrier layer 94 is formed on the spacer layer 93. The capping layer 95 is formed on the barrier layer 94. A source recess 970 and a drain recess 990 are etched such that a bottom 971 of the source recess 970 is defined by a top surface 930 of the spacer layer 93 and a bottom 991 of the drain recess 990 is defined by the top surface 930 of the spacer layer 93. The source electrode 97 is formed on the spacer layer 93 in the source recess 970 such that the source electrode 97 is in contact with the spacer layer 93. The drain electrode 99 is formed the spacer layer 93 in the drain recess 990 such that the drain electrode 99 is in contact with the spacer layer 93. The protection layer 96 is formed on the capping layer 95. A source opening 973 is etched and a source metal 972 is formed on the source electrode 97 in the source opening 973. A drain opening 993 is etched and a drain metal 992 is formed on the drain electrode 99 in the drain opening 993. A gate recess 980 is etched, wherein the gate recess 980 is located between the source electrode 97 and the drain electrode 99. The gate electrode 98 is formed on the capping layer 95 in the gate recess 980, wherein a bottom of the gate recess 980 is defined by the capping layer 95 such that the gate electrode 98 is in contact with the capping layer 95. The GaN-based field effect transistor 9 may be a GaN-based high electron mobility transistor.

Please refer to FIG. 3B, which shows a cross-sectional schematic view of another embodiment of a GaN-based field effect transistor of conventional technology. In the embodiment of FIG. 3B, the etching process (etching the source recess 970 and the drain recess 990) stopped in the barrier layer 94, wherein the bottom 971 of the source recess 970 is defined by the barrier layer 94 such that the source electrode 97 is in contact with the barrier layer 94, wherein the bottom 991 of the drain recess 990 is defined by the barrier layer 94 such that the drain electrode 99 is in contact with the barrier layer 94. In some embodiments, the bottom 971 of the source recess 970 is near the top surface 930 of the spacer layer 93, and the bottom 991 of the drain recess 990 is near the top surface 930 of the spacer layer 93. Please also refer to FIG. 3C, which shows a cross-sectional schematic view of an embodiment of a GaN-based field effect transistor of conventional technology. In the embodiment of FIG. 3C, the etching process (etching the source recess 970 and the drain recess 990) stopped in the spacer layer 93, wherein the bottom 971 of the source recess 970 is defined by the spacer layer 93 such that the source electrode 97 is in contact with the spacer layer 93, wherein the bottom 991 of the drain recess 990 is defined by the barrier layer 94 such that the drain electrode 99 is in contact with the spacer layer 93. In some embodiments, the bottom 971 of the source recess 970 is near the top surface 930 of the spacer layer 93, and the bottom 991 of the drain recess 990 is near the top surface 930 of the spacer layer 93.

The contact resistance (Rc) of each of the GaN-based field effect transistors 9 is strongly correlated to a depth of the source recess 970 and a depth of the drain recess 990. And also the on-resistance (Ron) of each of the GaN-based field effect transistors 9 is strongly correlated to the depth of the source recess 970 and the depth of the drain recess 990. The embodiment of FIG. 3A is an ideal embodiment, wherein the etching process (etching the source recess 970 and the drain recess 990) perfectly stopped at the top surface 930 of the spacer layer 93. Usually there are many GaN-based field effect transistors 9 formed on the same semiconductor substrate 90. During the etching process (etching the source recess 970 and the drain recess 990), the source recess 970 and the drain recess 990 of each of the GaN-based field effect transistors 9 is etched. However the etching process couldn't be so uniform, hence, it is not easy to control the depth of the source recess 970 and the depth of the drain recess 990 of each of the GaN-based field effect transistors 9 to be the same. That is that it is not easy to let the etching process (etching the source recess 970 and the drain recess 990) perfectly stopped at the top surface 930 of the spacer layer 93. Furthermore, the etching rate is determined by the crystallization and the thickness of the capping layer 95 and the crystallization and the thickness of the barrier layer 94. Therefore, in mass production, different batches of production, the crystallization and the thickness of the capping layer 95 and the barrier layer 94 may varies. Hence, it is quite difficult to control the depth of the source recess 970 and the depth of the drain recess 990 of each of the GaN-based field effect transistors 9 to be the same for all the batches of production. Therefore, some of the etching process (etching the source recess 970 and the drain recess 990) stopped in the barrier layer 94 (as the embodiment of FIG. 3B); some of the etching process (etching the source recess 970 and the drain recess 990) stopped in the spacer layer 93 (as the embodiment of FIG. 3C); and some of the etching process (etching the source recess 970 and the drain recess 990) perfectly stopped at the top surface 930 of the spacer layer 93 (as the embodiment of FIG. 3A). It results some defects on the performance of the GaN-based field effect transistors 9. First of all, some of the GaN-based field effect transistors 9 have a greater contact resistance; while some of the GaN-based field effect transistors 9 have a smaller contact resistance. The distribution of the contact resistance of the GaN-based field effect transistors 9 is non-uniform (scattered). The average of the contact resistance of the GaN-based field effect transistors 9 is raised such that the performance of the GaN-based field effect transistors 9 is reduced, especially when the bandgap of the spacer layer 93 is higher than the bandgap of the barrier layer 94. Furthermore, some of the GaN-based field effect transistors 9 have a greater on-resistance; while some of the GaN-based field effect transistors 9 have a smaller on-resistance. The distribution of the on-resistance of the GaN-based field effect transistors 9 is non-uniform (scattered). The average of the on-resistance of the GaN-based field effect transistors 9 is raised such that the performance of the GaN-based field effect transistors 9 is reduced, especially when the bandgap of the spacer layer 93 is higher than the bandgap of the barrier layer 94. Since the distribution of the contact resistance and the distribution of the on-resistance of the GaN-based field effect transistors 9 are non-uniform, the performance specifications of the GaN-based field effect transistors 9 are non-uniform.

Accordingly, the present invention has developed a new design which may avoid the above mentioned drawbacks, may significantly enhance the performance of the devices and may take into account economic considerations. Therefore, the present invention then has been invented.

### SUMMARY OF THE INVENTION

The main technical problem that the present invention is seeking to solve is to overcome the non-uniform distribution of the contact resistance and the non-uniform distribution of the on-resistance of the GaN-based field effect transistors, and, in the mean while, to reduce the average of the contact resistance and the average of the on-resistance of the GaN-based field effect transistors.

In order to solve the problems mentioned the above and to achieve the expected effect, the present invention provides a GaN-based field effect transistor comprising a semiconductor substrate, an epitaxial structure, a source electrode, a drain electrode and a gate electrode. The epitaxial structure is formed on the semiconductor substrate. The epitaxial structure comprises a buffer layer, a channel layer, an n-type doped barrier layer, a barrier layer, and a capping layer, wherein the buffer layer is formed on the semiconductor substrate, wherein the channel layer is formed on the buffer layer, wherein the n-type doped barrier layer is formed on the channel layer, wherein the barrier layer is formed on the n-type doped barrier layer, wherein the capping layer is formed on the barrier layer. The epitaxial structure has a source recess and a drain recess, wherein a bottom of the source recess is defined by the n-type doped barrier layer or a top surface of the channel layer, wherein a bottom of the drain recess is defined by the n-type doped barrier layer or the top surface of the channel layer. The source electrode is formed in the source recess. The drain electrode is formed in the drain recess. The gate electrode is formed on the capping layer between the source electrode and the drain electrode. By inserting the n-type doped barrier layer between the channel layer and the barrier layer, the contact resistance of the GaN-based field effect transistor is not strongly correlated to a depth of the source recess and a depth of the drain recess. Furthermore, the on-resistance of the GaN-based field effect transistor is not strongly correlated to the depth of the source recess and the depth of the drain recess either. Hence, the distribution of the contact resistance and the distribution of the on-resistance of the GaN-based field effect transistors are more uniform. The average of the contact resistance and the average of the on-resistance of the on-resistance of the GaN-based field effect transistors are reduced. The performance of the GaN-based field effect transistor is enhanced.

The present invention further provides a GaN-based field effect transistor comprising a semiconductor substrate, an epitaxial structure, a source electrode, a drain electrode and a gate electrode. The epitaxial structure is formed on the semiconductor substrate. The epitaxial structure comprises a buffer layer, a channel layer, a spacer layer, an n-type doped barrier layer, a barrier layer, and a capping layer, wherein the buffer layer is formed on the semiconductor substrate, wherein the channel layer is formed on the buffer layer, wherein the spacer layer is formed on the channel layer, wherein the n-type doped barrier layer is formed on the spacer layer, wherein the barrier layer is formed on the n-type doped barrier layer, wherein the capping layer is formed on the barrier layer. The epitaxial structure has a source recess and a drain recess, wherein a bottom of the source recess is defined by the n-type doped barrier layer or the spacer layer, wherein a bottom of the drain recess is defined by the n-type doped barrier layer or the spacer layer. The source electrode is formed in the source recess. The drain electrode is formed in the drain recess. The gate electrode is formed on the capping layer between the source electrode and the drain electrode. By inserting the n-type doped barrier layer between the spacer layer and the barrier layer, the contact resistance of the GaN-based field effect transistor is not strongly correlated to a depth of the source recess and a depth of the drain recess. Furthermore, the on-resistance of the GaN-based field effect transistor is not strongly correlated to the depth of the source recess and the depth of the drain recess either. Hence, the distribution of the contact resistance and the distribution of the on-resistance of the GaN-based field effect transistors are more uniform. The average of the contact resistance and the average of the on-resistance of the on-resistance of the GaN-based field effect transistors are reduced. The performance of the GaN-based field effect transistor is enhanced.

In an embodiment, the spacer layer is unintentionally doped.

In an embodiment, the bottom of the source recess is defined by a top surface of the spacer layer.

In an embodiment, the bottom of the drain recess is defined by a top surface of the spacer layer.

In an embodiment, the bottom of the source recess is defined by a top surface of the n-type doped barrier layer.

In an embodiment, the bottom of the drain recess is defined by a top surface of the n-type doped barrier layer.

In an embodiment, a thickness of the n-type doped barrier layer is greater than or equal to 1 nm and less than or equal to 10 nm.

In an embodiment, the n-type doped barrier layer is silicon doped.

In an embodiment, a doping concentration of the n-type doped barrier layer is greater than or equal to 5×10¹⁶ and less than or equal to 5×10¹⁸.

In an embodiment, the n-type doped barrier layer is made of at least one material selected from the group consisting of: AlGaN, InAlN, and AN.

In an embodiment, the barrier layer is made of at least one material selected from the group consisting of: AlGaN, InAlN, and AlN.

In an embodiment, the barrier layer is unintentionally doped.

In an embodiment, the channel layer is made of GaN.

In an embodiment, the buffer layer is made of at least one material selected from the group consisting of: GaN, AlGaN, and InGaN.

In an embodiment, the buffer layer is unintentionally doped.

In an embodiment, the buffer layer is doped with at least one material selected from the group consisting of: Fe, Mg, and C.

In an embodiment, the capping layer is made of GaN or AlN.

In an embodiment, the semiconductor substrate is made of one material selected from the group consisting of: SiC, sapphire, Si, diamond, and GaN.

In an embodiment, it further comprises a protection layer, wherein the protection layer is formed on the capping layer.

In an embodiment, the protection layer is made of at least one material selected from the group consisting of: AlOx, aluminium nitride, SiOy and silicon nitride, wherein the x is greater than or equal to 1 and less than or equal to 1.5, wherein the y is greater than or equal to 1 and less than or equal to 2.

In an embodiment, the GaN-based field effect transistor is a GaN-based high electron mobility transistor.

For further understanding the characteristics and effects of the present invention, some preferred embodiments referred to drawings are in detail described as follows.

### BRIEF DESCRIPTION OF DRAWINGS

FIG. 1A is a cross-sectional schematic view of an embodiment of a GaN-based field effect transistor of the present invention.

FIG. 1B is a cross-sectional schematic view of another embodiment of a GaN-based field effect transistor of the present invention.

FIG. 1C is a cross-sectional schematic view of an embodiment of a

GaN-based field effect transistor of the present invention.

FIG. 2A is a cross-sectional schematic view of another embodiment of a GaN-based field effect transistor of the present invention.

FIG. 2B is a cross-sectional schematic view of an embodiment of a GaN-based field effect transistor of the present invention.

FIG. 2C is a cross-sectional schematic view of another embodiment of a GaN-based field effect transistor of the present invention.

FIG. 2D is a graphical illustration comparatively showing the contact resistance (Rc) of the GaN-based field effect transistors of the present invention and that of the conventional technology.

FIG. 2E is a graphical illustration comparatively showing the on-resistance (Ron) of the GaN-based field effect transistors of the present invention and that of the conventional technology.

FIG. 3A is a cross-sectional schematic view of an embodiment of a GaN-based field effect transistor of conventional technology.

FIG. 3B is a cross-sectional schematic view of another embodiment of a GaN-based field effect transistor of conventional technology.

FIG. 3C is a cross-sectional schematic view of an embodiment of a GaN-based field effect transistor of conventional technology.

### DETAILED DESCRIPTIONS OF PREFERRED EMBODIMENTS

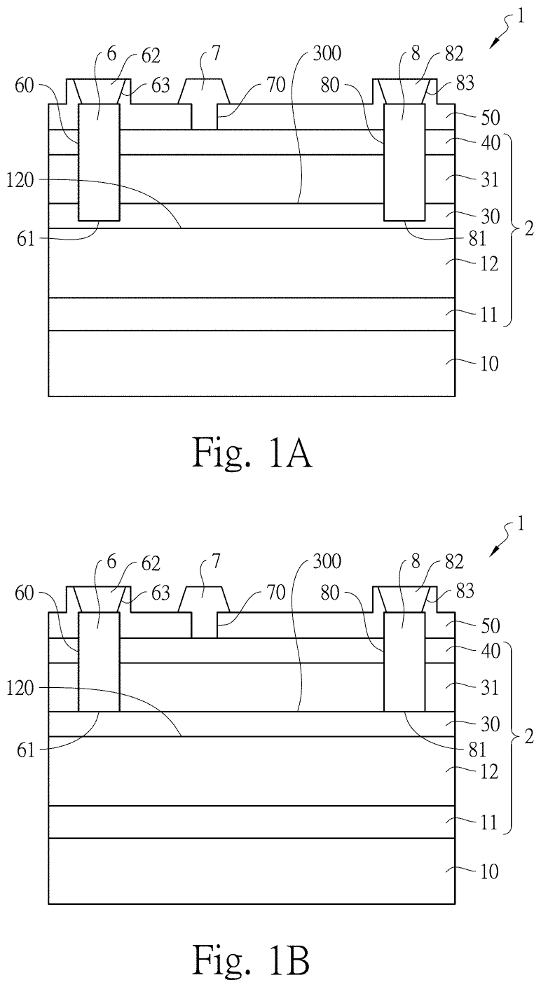

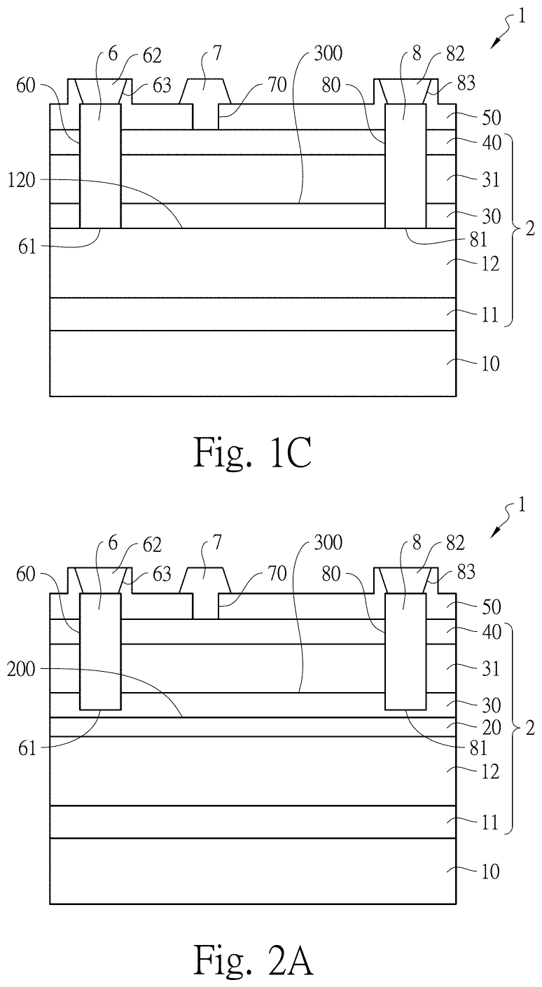

Please refer to FIG. 1A is a cross-sectional schematic view of an embodiment of a GaN-based field effect transistor of the present invention. The present invention provides a GaN-based field effect transistor 1 which comprises: a semiconductor substrate 10, an epitaxial structure 2, a protection layer 50, a source electrode 6, a drain electrode 8, and a gate electrode 7. The epitaxial structure 2 is formed on the semiconductor substrate 10, wherein the epitaxial structure 2 comprises: a buffer layer 11, a channel layer 12, an n-type doped barrier layer 30, a barrier layer 31, and a capping layer 40. The semiconductor substrate 10 is made of one material selected from the group consisting of: SiC, sapphire, Si, diamond, and GaN. The buffer layer 11 is formed on the semiconductor substrate 10. The buffer layer 11 is made of at least one material selected from the group consisting of: GaN, AlGaN, and InGaN. In some preferable embodiments, the buffer layer 11 is unintentionally doped. In some preferable embodiments, the buffer layer 11 is doped with at least one material selected from the group consisting of: Fe, Mg, and C. The channel layer 12 is formed on the buffer layer 11. The channel layer 12 is made of GaN. The n-type doped barrier layer 30 is formed on the channel layer 12. In some embodiments, the n-type doped barrier layer 30 is made of at least one material selected from the group consisting of: AlGaN, InAlN, and AlN. In some preferable embodiments, a thickness of the n-type doped barrier layer 30 is greater than or equal to 1 nm and less than or equal to 10 nm. In some other preferable embodiments, the n-type doped barrier layer 30 is silicon doped. In some preferable embodiments, a doping concentration of the n-type doped barrier layer 30 is greater than or equal to 5×10¹⁶ and less than or equal to 5×10¹⁸. The barrier layer 31 is formed on the n-type doped barrier layer 30. In some preferable embodiments, the barrier layer 31 is made of at least one material selected from the group consisting of: AlGaN, InAlN, and AlN. In some other preferable embodiments, the barrier layer 31 is unintentionally doped. The capping layer 40 is formed on the barrier layer 31. In some embodiments, the capping layer 40 is made of GaN or AlN. The epitaxial structure 2 has a source recess 60 and a drain recess 80. The source recess 60 is etched such that a bottom 61 of the source recess 60 is defined by the n-type doped barrier layer 30. The drain recess 80 is etched such that a bottom 81 of the drain recess 80 is defined by the n-type doped barrier layer 30. The source electrode 6 is formed on the n-type doped barrier layer 30 in the source recess 60, wherein the source electrode 6 is in contact with the n-type doped barrier layer 30. The drain electrode 8 is formed the n-type doped barrier layer 30 in the drain recess 80, wherein the drain electrode 8 is in contact with the n-type doped barrier layer 30. The protection layer 50 is formed on the capping layer 40. A source opening 63 is etched and a source metal 62 is formed on the source electrode 6 in the source opening 63. A drain opening 83 is etched and a drain metal 82 is formed on the drain electrode 8 in the drain opening 83. A gate recess 70 is etched, wherein the gate recess 70 is located between the source electrode 6 and the drain electrode 8. The gate electrode 7 is formed on the capping layer 40 in the gate recess 70, wherein a bottom of the gate recess 70 is defined by the capping layer 40 such that the gate electrode 7 is in contact with the capping layer 40. In some preferable embodiments, the protection layer 50 is made of at least one material selected from the group consisting of: AlOx, aluminium nitride, SiOy and silicon nitride, wherein the x is greater than or equal to 1 and less than or equal to 1.5, wherein the y is greater than or equal to 1 and less than or equal to 2. In some preferable embodiments, the GaN-based field effect transistor 1 is a GaN-based high electron mobility transistor.

In some embodiments, the thickness of the n-type doped barrier layer 30 is greater than or equal to 0.5 nm and less than or equal to 30 nm. In some other embodiments, the thickness of the n-type doped barrier layer 30 is greater than or equal to 0.8 nm and less than or equal to 30 nm. In some embodiments, the thickness of the n-type doped barrier layer 30 is greater than or equal to 1.5 nm and less than or equal to 30 nm. In some other embodiments, the thickness of the n-type doped barrier layer 30 is greater than or equal to 2 nm and less than or equal to 30 nm. In some embodiments, the thickness of the n-type doped barrier layer 30 is greater than or equal to 0.5 nm and less than or equal to 25 nm. In some other embodiments, the thickness of the n-type doped barrier layer 30 is greater than or equal to 0.5 nm and less than or equal to 20 nm. In some embodiments, the thickness of the n-type doped barrier layer 30 is greater than or equal to 0.5 nm and less than or equal to 15 nm. In some other embodiments, the thickness of the n-type doped barrier layer 30 is greater than or equal to 0.5 nm and less than or equal to 12 nm.

In some embodiments, a doping concentration of the n-type doped barrier layer 30 is greater than or equal to 1×10¹⁶ and less than or equal to 5×10¹⁸. In some other embodiments, a doping concentration of the n-type doped barrier layer 30 is greater than or equal to 1×10¹⁷ and less than or equal to 5×10¹⁸. In some embodiments, a doping concentration of the n-type doped barrier layer 30 is greater than or equal to 1×10¹⁶ and less than or equal to 1×10¹⁸. In some other embodiments, a doping concentration of the n-type doped barrier layer 30 is greater than or equal to 1×10¹⁷ and less than or equal to 1×10¹⁸. In some embodiments, a doping concentration of the n-type doped barrier layer 30 is greater than or equal to 3×10¹⁶ and less than or equal to 3×10¹⁸. In some other embodiments, a doping concentration of the n-type doped barrier layer 30 is greater than or equal to 3×10¹⁷ and less than or equal to 3×10¹⁸. In some embodiments, a doping concentration of the n-type doped barrier layer 30 is greater than or equal to 5×10¹⁶ and less than or equal to 1×10¹⁸. In some other embodiments, a doping concentration of the n-type doped barrier layer 30 is greater than or equal to 3×10¹⁷ and less than or equal to 1×10¹⁸.

Please refer to FIG. 1B is a cross-sectional schematic view of another embodiment of a GaN-based field effect transistor of the present invention. The main structure of the embodiment in FIG. 1B is basically the same as the structure of the embodiment in FIG. 1A, except that the bottom 61 of the source recess 60 is defined by a top surface 300 of the n-type doped barrier layer 30 such that the source electrode 6 is in contact with the n-type doped barrier layer 30, wherein the bottom 81 of the drain recess 80 is defined by the top surface 300 of the n-type doped barrier layer 30 such that the drain electrode 8 is in contact with the n-type doped barrier layer 30.

Please refer to FIG. 1C is a cross-sectional schematic view of an embodiment of a GaN-based field effect transistor of the present invention. The main structure of the embodiment in FIG. 1C is basically the same as the structure of the embodiment in FIG. 1A, except that the bottom 61 of the source recess 60 is defined by a top surface 120 of the channel layer 12 such that the source electrode 6 is in contact with the channel layer 12, wherein the bottom 81 of the drain recess 80 is defined by the top surface 120 of the channel layer 12 such that the drain electrode 8 is in contact with the channel layer 12.

It is difficult to control the etching process (etching the source recess 60 and the drain recess 80) such that a depth of the source recess 60 (related to the bottom 61 of the source recess 60) and a depth of the drain recess 80 (related to the bottom 81 of the drain recess 80) of each of the GaN-based field effect transistors 1 of the present invention to be the same. Hence, some of the GaN-based field effect transistors 1 of the present invention may have the same structure as the embodiment of FIG. 1A; some may have the same structure as the embodiment of FIG. 1B; and some may have the same structure as the embodiment of FIG. 1C. The present invention introduces the n-type doped barrier layer 30. By inserting the n-type doped barrier layer 30 between the channel layer 12 and the barrier layer 31, the contact resistance of the GaN-based field effect transistor 1 becomes not so strongly correlated to a depth of the source recess 60 (related to the bottom 61 of the source recess 60) and a depth of the drain recess 80 (related to the bottom 81 of the drain recess 80). Furthermore, the on-resistance of the GaN-based field effect transistor 1 becomes not so strongly correlated to the depth of the source recess 60 and the depth of the drain recess 80 either. Hence, the distribution of the contact resistance and the distribution of the on-resistance of the GaN-based field effect transistors 1 are more uniform. The average of the contact resistance and the average of the on-resistance of the on-resistance of the GaN-based field effect transistors 1 are reduced. The performance of the GaN-based field effect transistor 1 is enhanced.

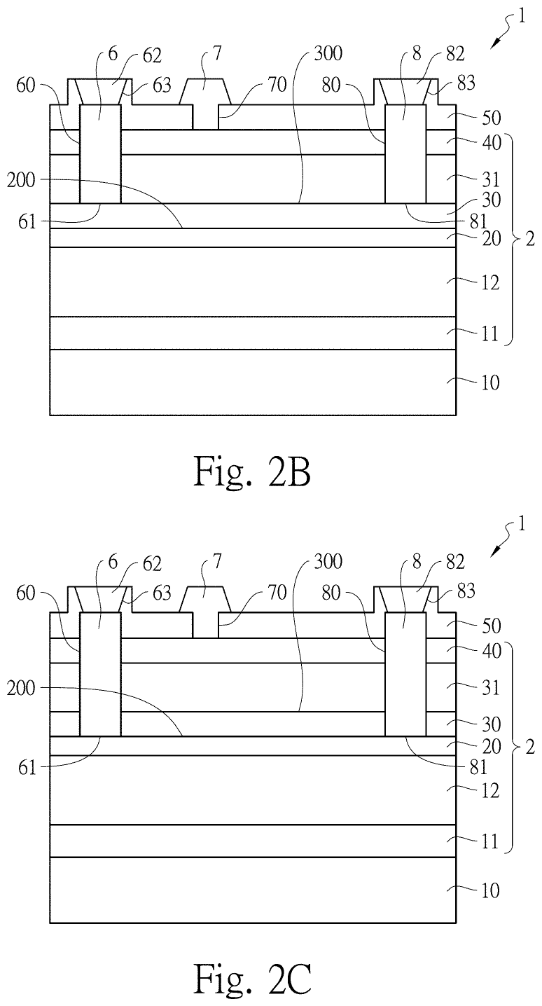

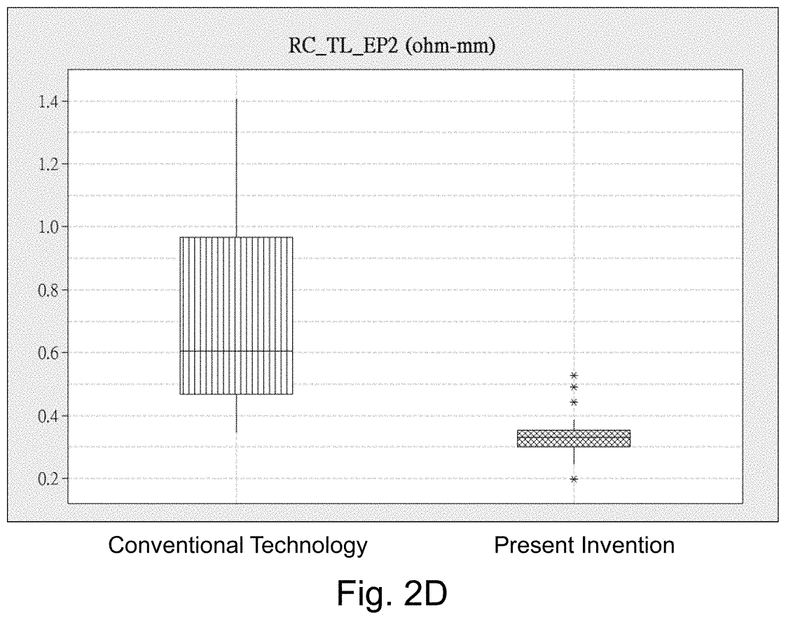

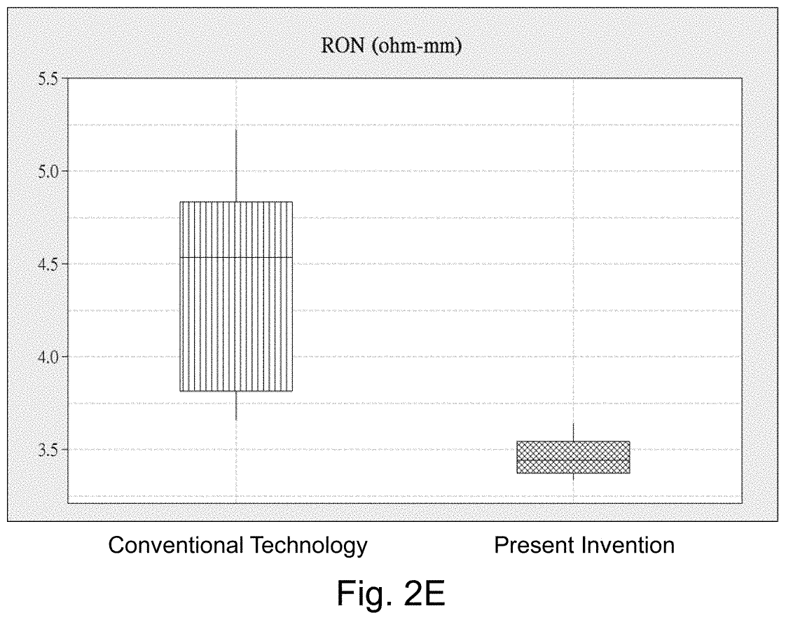

Please refer to FIG. 2A is a cross-sectional schematic view of another embodiment of a GaN-based field effect transistor of the present invention. The present invention further provides a GaN-based field effect transistor 1 which comprises: a semiconductor substrate 10, an epitaxial structure 2, a protection layer 50, a source electrode 6, a drain electrode 8, and a gate electrode 7. The epitaxial structure 2 is formed on the semiconductor substrate 10, wherein the epitaxial structure 2 comprises: a buffer layer 11, a channel layer 12, a spacer layer 20, an n-type doped barrier layer 30, a barrier layer 31, and a capping layer 40. The semiconductor substrate 10 is made of one material selected from the group consisting of: SiC, sapphire, Si, diamond, and GaN. The buffer layer 11 is formed on the semiconductor substrate 10. The buffer layer 11 is made of at least one material selected from the group consisting of: GaN, AlGaN, and InGaN. In some preferable embodiments, the buffer layer 11 is unintentionally doped. In some preferable embodiments, the buffer layer 11 is doped with at least one material selected from the group consisting of: Fe, Mg, and C. The channel layer 12 is formed on the buffer layer 11. The channel layer 12 is made of GaN. The spacer layer 20 is formed on the channel layer 12. The spacer layer 20 materials. In some preferable embodiments, the spacer layer 20 is unintentionally doped. The n-type doped barrier layer 30 is formed on the spacer layer 20. In some embodiments, the n-type doped barrier layer 30 is made of at least one material selected from the group consisting of: AlGaN, InAlN, and AlN. In some preferable embodiments, a thickness of the n-type doped barrier layer 30 is greater than or equal to 1 nm and less than or equal to 10 nm. In some other preferable embodiments, the n-type doped barrier layer 30 is silicon doped. In some preferable embodiments, a doping concentration of the n-type doped barrier layer 30 is greater than or equal to 5×10¹⁶ and less than or equal to 5×10¹⁸. The barrier layer 31 is formed on the n-type doped barrier layer 30. In some preferable embodiments, the barrier layer 31 is made of at least one material selected from the group consisting of: AlGaN, InAlN, and AlN. In some other preferable embodiments, the barrier layer 31 is unintentionally doped. The capping layer 40 is formed on the barrier layer 31. In some embodiments, the capping layer 40 is made of GaN or AlN.

In some embodiments, the thickness of the n-type doped barrier layer 30 is greater than or equal to 0.5 nm and less than or equal to 30 nm. In some other embodiments, the thickness of the n-type doped barrier layer 30 is greater than or equal to 0.8 nm and less than or equal to 30 nm. In some embodiments, the thickness of the n-type doped barrier layer 30 is greater than or equal to 1.5 nm and less than or equal to 30 nm. In some other embodiments, the thickness of the n-type doped barrier layer 30 is greater than or equal to 2 nm and less than or equal to 30 nm. In some embodiments, the thickness of the n-type doped barrier layer 30 is greater than or equal to 0.5 nm and less than or equal to 25 nm. In some other embodiments, the thickness of the n-type doped barrier layer 30 is greater than or equal to 0.5 nm and less than or equal to 20 nm. In some embodiments, the thickness of the n-type doped barrier layer 30 is greater than or equal to 0.5 nm and less than or equal to 15 nm. In some other embodiments, the thickness of the n-type doped barrier layer 30 is greater than or equal to 0.5 nm and less than or equal to 12 nm.

In some embodiments, a doping concentration of the n-type doped barrier layer 30 is greater than or equal to 1×10¹⁶ and less than or equal to 5×10¹⁸. In some other embodiments, a doping concentration of the n-type doped barrier layer 30 is greater than or equal to 1×10¹⁷ and less than or equal to 5×10¹⁸. In some embodiments, a doping concentration of the n-type doped barrier layer 30 is greater than or equal to 1×10¹⁶ and less than or equal to 1×10¹⁸. In some other embodiments, a doping concentration of the n-type doped barrier layer 30 is greater than or equal to 1×10¹⁷ and less than or equal to 1×10¹⁸. In some embodiments, a doping concentration of the n-type doped barrier layer 30 is greater than or equal to 3×10¹⁶ and less than or equal to 3×10¹⁸. In some other embodiments, a doping concentration of the n-type doped barrier layer 30 is greater than or equal to 3×10¹⁷ and less than or equal to 3×10¹⁸. In some embodiments, a doping concentration of the n-type doped barrier layer 30 is greater than or equal to 5×10¹⁶ and less than or equal to 1×10¹⁸. In some other embodiments, a doping concentration of the n-type doped barrier layer 30 is greater than or equal to 3×10¹⁷ and less than or equal to 1×10¹⁸.

The epitaxial structure 2 has a source recess 60 and a drain recess 80. The source recess 60 is etched such that a bottom 61 of the source recess 60 is defined by the n-type doped barrier layer 30. The drain recess 80 is etched such that a bottom 81 of the drain recess 80 is defined by the n-type doped barrier layer 30. The source electrode 6 is formed on the n-type doped barrier layer 30 in the source recess 60, wherein the source electrode 6 is in contact with the n-type doped barrier layer 30. The drain electrode 8 is formed the n-type doped barrier layer 30 in the drain recess 80, wherein the drain electrode 8 is in contact with the n-type doped barrier layer 30. The protection layer 50 is formed on the capping layer 40. A source opening 63 is etched and a source metal 62 is formed on the source electrode 6 in the source opening 63. A drain opening 83 is etched and a drain metal 82 is formed on the drain electrode 8 in the drain opening 83. A gate recess 70 is etched, wherein the gate recess 70 is located between the source electrode 6 and the drain electrode 8. The gate electrode 7 is formed on the capping layer 40 in the gate recess 70, wherein a bottom of the gate recess 70 is defined by the capping layer 40 such that the gate electrode 7 is in contact with the capping layer 40. In some preferable embodiments, the protection layer 50 is made of at least one material selected from the group consisting of: AlOx, aluminium nitride, SiOy and silicon nitride, wherein the x is greater than or equal to 1 and less than or equal to 1.5, wherein the y is greater than or equal to 1 and less than or equal to 2. In some preferable embodiments, the GaN-based field effect transistor 1 is a GaN-based high electron mobility transistor.

Please refer to FIG. 2B is a cross-sectional schematic view of an embodiment of a GaN-based field effect transistor of the present invention. The main structure of the embodiment in FIG. 2B is basically the same as the structure of the embodiment in FIG. 2A, except that the bottom 61 of the source recess 60 is defined by a top surface 300 of the n-type doped barrier layer 30 such that the source electrode 6 is in contact with the n-type doped barrier layer 30, wherein the bottom 81 of the drain recess 80 is defined by the top surface 300 of the n-type doped barrier layer 30 such that the drain electrode 8 is in contact with the n-type doped barrier layer 30.

Please refer to FIG. 2C is a cross-sectional schematic view of another embodiment of a GaN-based field effect transistor of the present invention. The main structure of the embodiment in FIG. 2C is basically the same as the structure of the embodiment in FIG. 2A, except that the bottom 61 of the source recess 60 is defined by a top surface 200 of the spacer layer 20 such that the source electrode 6 is in contact with the spacer layer 20, wherein the bottom 81 of the drain recess 80 is defined by the top surface 200 of the spacer layer 20 such that the drain electrode 8 is in contact with the spacer layer 20.

It is difficult to control the etching process (etching the source recess 60 and the drain recess 80) such that a depth of the source recess 60 (related to the bottom 61 of the source recess 60) and a depth of the drain recess 80 (related to the bottom 81 of the drain recess 80) of each of the GaN-based field effect transistors 1 of the present invention to be the same. Hence, some of the GaN-based field effect transistors 1 of the present invention may have the same structure as the embodiment of FIG. 2A; some may have the same structure as the embodiment of FIG. 2B; and some may have the same structure as the embodiment of FIG. 2C. The present invention introduces the n-type doped barrier layer 30. By inserting the n-type doped barrier layer 30 between the spacer layer 20 and the barrier layer 31, the contact resistance of the GaN-based field effect transistor 1 becomes not so strongly correlated to a depth of the source recess 60 (related to the bottom 61 of the source recess 60) and a depth of the drain recess 80 (related to the bottom 81 of the drain recess 80). Furthermore, the on-resistance of the GaN-based field effect transistor 1 becomes not so strongly correlated to the depth of the source recess 60 and the depth of the drain recess 80 either. Hence, the distribution of the contact resistance and the distribution of the on-resistance of the GaN-based field effect transistors 1 are more uniform. The average of the contact resistance and the average of the on-resistance of the on-resistance of the GaN-based field effect transistors 1 are reduced. The performance of the GaN-based field effect transistor 1 is enhanced.

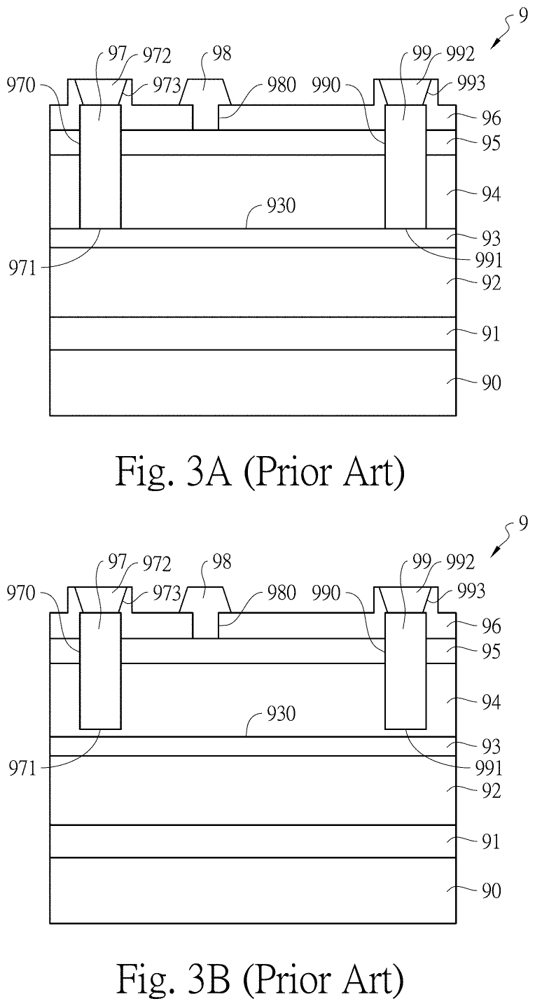

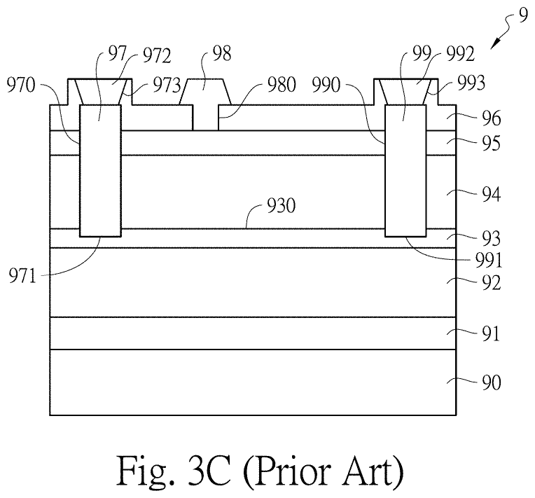

Please refer to FIG. 2D, which is a graphical illustration comparatively showing the contact resistance (Rc) of the GaN-based field effect transistors of the present invention and that of the conventional technology. And Please also refer to FIG. 2E, which is a graphical illustration comparatively showing the on-resistance (Ron) of the GaN-based field effect transistors of the present invention and that of the conventional technology. The samples of the GaN-based field effect transistors 9 of the convention technology been tested may have different structures. Some of the GaN-based field effect transistors 9 of the convention technology may have the same structure as the embodiment of FIG. 3A; some may have the same structure as the embodiment of FIG. 3B; and some may have the same structure as the embodiment of FIG. 3C. The samples of the GaN-based field effect transistors 1 of the present invention been tested may have different structures. Some of the GaN-based field effect transistors 1 of the present invention may have the same structure as the embodiment of FIG. 2A; some may have the same structure as the embodiment of FIG. 2B; and some may have the same structure as the embodiment of FIG. 2C. In FIG. 2D, the result shows very clearly that the distribution of the contact resistance of the GaN-based field effect transistors 9 of the conventional technology is non-uniform, while the distribution of the contact resistance of the GaN-based field effect transistors 1 of the present invention is more uniform. Furthermore, the average of the contact resistance of the GaN-based field effect transistors 9 of the conventional technology is higher than the average of the contact resistance of the GaN-based field effect transistors 1 of the present invention. In FIG. 2E, the result shows very clearly that the distribution of the on-resistance of the GaN-based field effect transistors 9 of the conventional technology is non-uniform, while the distribution of the on-resistance of the GaN-based field effect transistors 1 of the present invention is more uniform. Furthermore, the average of the on-resistance of the GaN-based field effect transistors 9 of the conventional technology is higher than the average of the on-resistance of the GaN-based field effect transistors 1 of the present invention. Hence, the performance of the GaN-based field effect transistors 1 of the present invention is enhanced.

As disclosed in the above description and attached drawings, the present invention can provide a GaN-based field effect transistor. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. A GaN-based field effect transistor comprising:
a semiconductor substrate;
an epitaxial structure formed on said semiconductor substrate, wherein said epitaxial structure comprises:
a buffer layer formed on said semiconductor substrate;
a channel layer formed on said buffer layer;
an n-type doped barrier layer formed on said channel layer;
a barrier layer formed on said n-type doped barrier layer;
a capping layer formed on said barrier layer;
wherein said epitaxial structure has a source recess and a drain recess, wherein a bottom of said source recess is defined by said n-type doped barrier layer or a top surface of said channel layer, wherein a bottom of said drain recess is defined by said n-type doped barrier layer or said top surface of said channel layer;
a source electrode formed in said source recess;
a drain electrode formed in said drain recess; and
a gate electrode formed on said capping layer between said source electrode and said drain electrode.

2. The GaN-based field effect transistor according to claim 1, wherein said bottom of said source recess is defined by a top surface of said n-type doped barrier layer.

3. The GaN-based field effect transistor according to claim 1, wherein said bottom of said drain recess is defined by a top surface of said n-type doped barrier layer.

4. The GaN-based field effect transistor according to claim 1, wherein a thickness of said n-type doped barrier layer is greater than or equal to 1 nm and less than or equal to 10 nm.

5. The GaN-based field effect transistor according to claim 1, wherein said n-type doped barrier layer is silicon doped.

6. The GaN-based field effect transistor according to claim 1, wherein a doping concentration of said n-type doped barrier layer is greater than or equal to 5×10¹⁶ and less than or equal to 5×10¹⁸.

7. The GaN-based field effect transistor according to claim 1, wherein said n-type doped barrier layer is made of at least one material selected from the group consisting of: AlGaN, InAlN, and AlN.

8. The GaN-based field effect transistor according to claim 1, wherein said barrier layer is made of at least one material selected from the group consisting of: AlGaN, InAlN, and AlN.

9. The GaN-based field effect transistor according to claim 8, wherein said barrier layer is unintentionally doped.

10. The GaN-based field effect transistor according to claim 1, wherein said channel layer is made of GaN.

11. The GaN-based field effect transistor according to claim 1, wherein said buffer layer is made of at least one material selected from the group consisting of: GaN, AlGaN, and InGaN.

12. The GaN-based field effect transistor according to claim 11, wherein said buffer layer is unintentionally doped.

13. The GaN-based field effect transistor according to claim 11, wherein said buffer layer is doped with at least one material selected from the group consisting of: Fe, Mg, and C.

14. The GaN-based field effect transistor according to claim 1, wherein said capping layer is made of GaN or AlN.

15. The GaN-based field effect transistor according to claim 1, wherein said semiconductor substrate is made of one material selected from the group consisting of: SiC, sapphire, Si, diamond, and GaN.

16. The GaN-based field effect transistor according to claim 1, further comprising a protection layer, wherein said protection layer is formed on said capping layer.

17. The GaN-based field effect transistor according to claim 16, wherein said protection layer is made of at least one material selected from the group consisting of: AlOx, aluminium nitride, SiOy and silicon nitride, wherein said x is greater than or equal to 1 and less than or equal to 1.5, wherein said y is greater than or equal to 1 and less than or equal to 2.

18. The GaN-based field effect transistor according to claim 1, wherein said GaN-based field effect transistor is a GaN-based high electron mobility transistor.

19. A GaN-based field effect transistor comprising:
a semiconductor substrate;
an epitaxial structure formed on said semiconductor substrate, wherein said epitaxial structure comprises:
a buffer layer formed on said semiconductor substrate;
a channel layer formed on said buffer layer;
a spacer layer formed on said channel layer;
an n-type doped barrier layer formed on said spacer layer;
a barrier layer formed on said n-type doped barrier layer;
a capping layer formed on said barrier layer;
wherein said epitaxial structure has a source recess and a drain recess, wherein a bottom of said source recess is defined by said n-type doped barrier layer or said spacer layer, wherein a bottom of said drain recess is defined by said n-type doped barrier layer or said spacer layer;
a source electrode formed in said source recess;
a drain electrode formed in said drain recess; and
a gate electrode formed on said capping layer between said source electrode and said drain electrode.

20. The GaN-based field effect transistor according to claim 19, wherein said bottom of said source recess is defined by a top surface of said n-type doped barrier layer.

21. The GaN-based field effect transistor according to claim 19, wherein said bottom of said drain recess is defined by a top surface of said n-type doped barrier layer.

22. The GaN-based field effect transistor according to claim 19, wherein a thickness of said n-type doped barrier layer is greater than or equal to 1 nm and less than or equal to 10 nm.

23. The GaN-based field effect transistor according to claim 19, wherein said n-type doped barrier layer is silicon doped.

24. The GaN-based field effect transistor according to claim 19, wherein a doping concentration of said n-type doped barrier layer is greater than or equal to 5×10¹⁶ and less than or equal to 5×10¹⁸.

25. The GaN-based field effect transistor according to claim 19, wherein said n-type doped barrier layer is made of at least one material selected from the group consisting of: AlGaN, InAlN, and AlN.

26. The GaN-based field effect transistor according to claim 19, wherein said barrier layer is made of at least one material selected from the group consisting of: AlGaN, InAlN, and AlN.

27. The GaN-based field effect transistor according to claim 26, wherein said barrier layer is unintentionally doped.

28. The GaN-based field effect transistor according to claim 19, wherein said channel layer is made of GaN.

29. The GaN-based field effect transistor according to claim 19, wherein said buffer layer is made of at least one material selected from the group consisting of: GaN, AlGaN, and InGaN.

30. The GaN-based field effect transistor according to claim 29, wherein said buffer layer is unintentionally doped.

31. The GaN-based field effect transistor according to claim 29, wherein said buffer layer is doped with at least one material selected from the group consisting of: Fe, Mg, and C.

32. The GaN-based field effect transistor according to claim 19, wherein said capping layer is made of GaN or AlN.

33. The GaN-based field effect transistor according to claim 19, wherein said semiconductor substrate is made of one material selected from the group consisting of: SiC, sapphire, Si, diamond, and GaN.

34. The GaN-based field effect transistor according to claim 19, further comprising a protection layer, wherein said protection layer is formed on said capping layer.

35. The GaN-based field effect transistor according to claim 34, wherein said protection layer is made of at least one material selected from the group consisting of: AlOx, aluminium nitride, SiOy and silicon nitride, wherein said x is greater than or equal to 1 and less than or equal to 1.5, wherein said y is greater than or equal to 1 and less than or equal to 2.

36. The GaN-based field effect transistor according to claim 19, wherein said spacer layer is unintentionally doped.

37. The GaN-based field effect transistor according to claim 19, wherein said bottom of said source recess is defined by a top surface of said spacer layer.

38. The GaN-based field effect transistor according to claim 19, wherein said bottom of said drain recess is defined by a top surface of said spacer layer.

39. The GaN-based field effect transistor according to claim 19, wherein said GaN-based field effect transistor is a GaN-based high electron mobility transistor.
